(19) United States
(12) Patent Application Publication
(10) Pub. No.: US 2021/0280563 A1
(43) Pub. Date: Sep. 9, 2021

(54) SEMICONDUCTOR DEVICE, FABRICATION METHOD THEREOF, PACKAGE AND FABRICATION METHOD THEREOF

(71) Applicant: Changxin Memory Technologies, Inc., Hefei (CN)

(72) Inventors: Ping-Heng WU, HEFEI (CN); Mei-Li WANG, HEFEI (CN)

(21) Appl. No.: 17/328,154

(22) Filed: May 24, 2021

Related U.S. Application Data
(63) Continuation of application No. PCT/CN2019/120074, filed on Nov. 22, 2019.

(30) Foreign Application Priority Data
Nov. 28, 2018 (CN) 201811434025.7
Nov. 28, 2018 (CN) 201821974884.0

(51) Int. Cl. H01L 25/065; H01L 23/538; H01L 23/00; H01L 21/768

(52) U.S. Cl. CPC H01L 25/0657; H01L 23/5386; H01L 21/768; H01L 23/5384; H01L 24/14

(57) ABSTRACT

A semiconductor device is disclosed. The device includes a stacked structure and an electrode. The stacked structure includes at least one die, the electrode is located on a side surface of the stacked structure, and the electrode has a length greater than or equal to a thickness of the die in a thickness direction of the die. The semiconductor device does not need a micro-bump for connection, thereby allowing a thinner stacked structure. The electrodes are disposed on the side surface of the stacked structure. Thus, it is not necessary to provide a connection at the wiring layer or reserve connection position when designing the circuit. The length of the electrode in the thickness direction of the die is greater than or equal to the thickness of the die, facilitating the connection of circuits on a plurality of dies.

### CROSS-REFERENCE TO RELATED APPLICATIONS

This application is a continuation application of International Patent Application No. PCT/CN2019/120074, which is based on and claims priority of Chinese Patent Applications No. 201811434025.7 and No. 201821974884.0, both filed on Nov. 28, 2018. The above-referenced applications are incorporated herein by reference in their entirety.

### TECHNICAL FIELD

This present invention relates generally to the field of semiconductor technologies and, more specifically, to a semiconductor device and a method of fabricating the semiconductor device, a package having the semiconductor device, and a method of fabricating the package.

### BACKGROUND

High-capacity, small-size memories are occupying an increasingly larger market share.

FIG. 1 is a schematic diagram of a connection structure of a die stacking structure in the prior art. As shown in FIG. 1, when stacked together, several dies 1 may be connected with each other via through silicon vias (TSV) 2 or micro bumps 3. To ensure good soldering and reliable electrical conductivity, the micro bumps 3 need to have a sufficiently large size, which may limit the layout design of the circuit and may be a limiting factor in developing high-capacity and small-size memories. The effective heat dissipation area of existing memories is constrained, which also limits the memory capacity. Moreover, as the size of the package structure is limited by the length and width of the die 1, existing memories are difficult to be further miniaturized.

Therefore, a semiconductor device/package and related fabricating methods that can address the aforementioned limitations are desired.

It is to be noted that the information disclosed in this Background section is only for facilitating the understanding of the background of the invention and therefore may contain information that does not form the prior art that is already known to a person of ordinary skill in the art.

### SUMMARY

In view of the deficiencies of existing technologies that limit the capacity and miniaturization of memories, as described above, the present invention provides a semiconductor device and a manufacturing method thereof capable of achieving high capacity and thinness, and a semiconductor package having the semiconductor device and a method of fabricating the package.

Additional aspects and advantages of the present invention will be set forth in part in the description which follows, and it will be apparent from the description, or may be learned by the practice of the invention.

One aspect of the present invention is directed to a semiconductor device. The device may include: a stacked structure comprising a plurality of dies; an electrode formed on a side surface of the stacked structure, the electrode having a length greater than or equal to a thickness of the die in a thickness direction of the stacked structure; and a bump covering the electrode and disposed on a side of the electrode facing away from the plurality of dies, the bump electrically connecting one or more selected dies in the plurality of dies.

In some embodiments of the present invention, the device may further include: a wiring layer formed on each of the plurality of dies; and a plurality of signal terminal disposed in each of the wiring layers and electrically connected to the electrode via the wiring layers.

In some embodiments of the present invention, the bump may cover junctions of the electrode and the wiring layers.

In some embodiments of the present invention, the length of the bump may be greater than or equal to the length of the electrode, and the width of the bump may be greater than or equal to the width of the electrode.

Another aspect of the present invention is directed to a semiconductor package. The semiconductor package may include: the semiconductor device as described in any of the aforementioned embodiments; and a package substrate disposed on the side surface of the stacked structure and electrically connected to the electrode.

In some embodiments of the present invention, the semiconductor package may further include: a package film disposed on the surface of the stacked structure no disposed with the package substrate.

Another aspect of the present invention is directed to a semiconductor device. The device may include: a stacked structure including at least one die; and an electrode formed on the side surface of the stacked structure. The electrode may have the length greater than or equal to the thickness of the die in the thickness direction of the die.

In some embodiments of the present invention, the semiconductor device may further include: a wiring layer formed on the die; and a plurality of signal terminals disposed in the wiring layer and electrically connected to the electrode via the wiring layer.

In some embodiments of the present invention, the stack structure may further include: the first die; and the second die formed on the first die.

In some embodiments of the present invention, the semiconductor device may further include: the first wiring layer disposed on the first die; and the second wiring layer disposed on the second die. The first wiring layer may be electrically connected to the second wiring layer through the Through Silicon Via (TSV).

In some embodiments of the present invention, the electrode may be electrically connected to at least one of the first wiring layer and the second wiring layer.

In some embodiments of the present invention, the die may have a notch, and the electrode may be disposed in the notch.

In some embodiments of the present invention, the semiconductor device may further include: a bump disposed on a side of the electrode facing away from the die. The bump may protrude from the notch.

In some embodiments of the present invention, the bump may cover the electrode and the junction of the electrode and the wiring layer.

Another aspect of the present invention is directed to a method of fabricating a semiconductor device. The method may include: forming a stacked structure, the stacked structure including at least one die; and forming an electrode on the side surface of the stacked structure. The electrode may have the length greater than or equal to the thickness of the die in the thickness direction of the die.

In some embodiments of the present invention, the method may include: before forming a stacked structure, forming a wiring layer on the die. The electrode may be electrically connected to the wiring layer.

In some embodiments of the present invention, forming a stacked structure may include: forming the first die; and forming the second die on the first die.

In some embodiments of the present invention, the method may further include: forming the first wiring layer on the first die; forming the second wiring layer on the second die; and forming the first TSV on the first die. The first TSV may be electrically connecting the first wiring layer and the second wiring layer.

In some embodiments of the present invention, the method may further include forming the second TSV in a sealing region of the second die while forming the first TSV.

In some embodiments of the present invention, forming an electrode on a side surface of the stacked structure may include: removing at least a portion of the sealing region to expose the second TSV to form the electrode. The electrode may be arranged on the side surface of the stacked structure.

In some embodiments of the present invention, the method may further include: after forming an electrode on a side surface of the stacked structure, forming a bump on the side of the electrode facing away from the die.

Another aspect of the present invention is directed to a method of fabricating a semiconductor package. The method may include: forming the semiconductor device described in any of the aforementioned embodiments; and forming a package substrate on the side surface of the stacked structure. The package substrate may be electrically connecting to the electrode.

In some embodiments of the present invention, the method may further include: forming a package film on the surface of the stacked structure not disposed with the package substrate.

As can be seen from the above technical solutions, the present invention has at least one of the following advantages and positive effects.

The semiconductor device of the present invention includes a stacked structure of at least one die, the electrodes are located on side surfaces of the stacked structure, and the length of the electrodes in the thickness direction of the die may be greater than or equal to the thickness of the die. Therefore, the semiconductor device does not need a micro-bump for connection, and the thickness of the stacked structure may be further reduced, thereby facilitating the miniaturization of the device. Further, the electrodes are disposed on the side surface of the stacked structure, and it is not necessary to provide a connection at the wiring layer. When designing a circuit, it is not necessary to reserve connection positions that may limit the circuit layout on the die. Additionally, the length of the electrode in the thickness direction of the die may be greater than or equal to the thickness of the die, facilitating the connection of circuits on the plurality of dies.

The semiconductor package of the present invention may include the above semiconductor device, and a package substrate may be provided on the side surface of the stacked structure. The package substrate may be electrically connected to the electrode. The package substrate may be disposed on the side surface of the stacked structure, which may be made thinner. Additionally, the upper and lower surfaces of the stacked structure may serve as heat dissipating surfaces, thereby increasing the effective heat dissipating area, and accommodating for memories of higher capacity.

### BRIEF DESCRIPTION OF THE DRAWINGS

The above and other features and advantages of the present invention will become more apparent from the detailed description of the exemplary embodiments.

FIG. 1 is a schematic diagram of a connection structure of a die stacking structure in the prior art.

FIG. 2 is a schematic view of a semiconductor device in accordance with one embodiment of the present invention.

FIG. 3 is a perspective view showing the structure of the semiconductor device shown in FIG. 2.

FIG. 4 is a schematic view of a semiconductor device in accordance with another embodiment of the present invention.

FIG. 5 is a flow chart illustrating a method of fabricating a semiconductor device in accordance with one embodiment of the present invention.

FIG. 6 is a schematic view of a die in accordance with one embodiment of the present invention.

FIG. 7 is a schematic view showing the structure of forming a TSV in the sealing region of the die in accordance with one embodiment of the present invention.

FIG. 8 is a schematic view of a die after forming a stacked structure in accordance with one embodiment of the present invention.

FIG. 9 is a schematic view showing the structure after removing a part of the sealing region of the die in accordance with one embodiment of the present invention.

FIG. 10 is a schematic view of a stacked structure after forming a bump in accordance with one embodiment of the present invention.

FIG. 11 is a partial top view of the structure of FIG. 10.

FIG. 12 is a schematic view of a semiconductor package in accordance with one embodiment of the present invention.

FIG. 13 is a top view of the structure of FIG. 12.

FIG. 14 is a flow chart illustrating a method of fabricating a semiconductor package in accordance with one embodiment of the present invention.

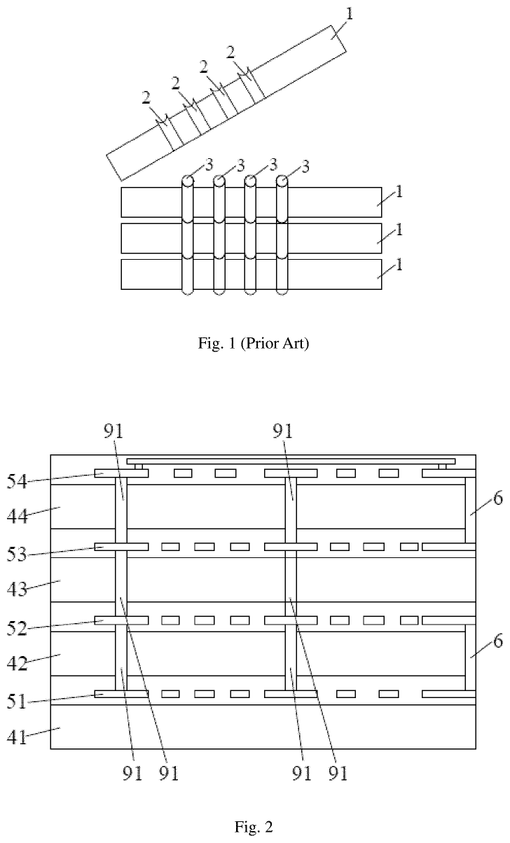

The main component reference numerals in the figures are as follows:

In the prior art:
1: die; 2: through silicon vias; 3: micro bumps.

In the present invention:
41: first die; 42: first sub-die; 43: second sub-die; 44: third sub-die; 51: first wiring layer; 52: second wiring layer; 53: third wiring layer; 54: fourth wiring layer; 6: electrode; 61: first electrode; 62: second electrode; 63: third electrode; 64: fourth electrode; 65: fifth electrode; 7: bump; 8: die; 815: circuit area; 82: sealing region; 83: lead wire; 91: first TSV; 92: second TSV; 10: package substrate; 11: package film; 121: first signal terminal; 122: second signal terminal; 123: third signal terminal; 124: fourth signal terminal; 125: fifth signal terminal.

### DETAIL DESCRIPTION OF THE EMBODIMENTS

Exemplary embodiments will now be described more fully with reference to the accompanying drawings. However, these exemplary embodiments can be implemented in many forms and should not be construed as being limited to those set forth herein. Rather, these embodiments are presented to provide a full and thorough understanding of the present invention and to fully convey the concepts of the exemplary embodiments to others skilled in the art. Throughout the drawings, like reference numbers indicate identical or similar elements, so any duplicate description of them will be omitted.

The present invention provides a semiconductor device, which may include a stacked structure, a wiring layer and an electrode. The stacked structure may include at least one die, the electrode may be located at the side surface of the stacked structure, and the length of the electrode in the thickness direction of the die may be greater than or equal to the thickness of the die.

The semiconductor device of the present invention does not need micro-bumps for connections, and the thickness of the stacked structure may be further reduced, thereby facilitating the miniaturization of the device. Further, the electrodes are disposed on the side surface of the stacked structure, and it is not necessary to provide a connection at the wiring layer. When designing a circuit, it is not necessary to reserve connection positions that may limit the circuit layout on the die. Additionally, the length of the electrode in the thickness direction of the die may be greater than or equal to the thickness of the die, facilitating the connection of circuits on the plurality of dies.

In the present exemplary embodiment, the side on which the die is provided with the wiring layer is “upper”, the side opposite to “upper” is “lower”, and the side between the upper and lower sides is the side surface.

The stacked structure may include only the first die and may also include the first die and the second die, and the second die may include one or more layers of dies.

FIG. 2 is a schematic view of a semiconductor device in accordance with one embodiment of the present invention. Referring to FIG. 2, the stack structure may include four layers of dies. For the convenience of the following description, the four layers of dies may be referred to as the first die 41, the first sub-die 42, the second sub-die 43 and the third sub-die 44, respectively, from the bottom to the top. The first sub-die 42, the second sub-die 43 and the third sub-die 44 may form the second die. A wiring layer may be provided on each of the dies. The wiring layer on the first die 41 may be referred to as the first wiring layer 51, the wiring layer on the first sub-die 42 may be referred to as the second wiring layer 52, and the wiring layer on the second sub-die 43 may be referred to as the third wiring layer 53, the wiring layer on the third sub-die 44 may be referred to as the fourth wiring layer 54. In addition, the specific structure of the stacked structure may not be limited to the above description. For example, the stacked structure may include only one layer of die, two layers of dies, three layers of dies, five layers of dies, or more layers of dies.

Referring to the schematic diagram of an exemplary embodiment of the semiconductor device shown in FIG. 2. The first wiring layer 51, the second wiring layer 52, the third wiring layer 53 and the fourth wiring layer 54 may be electrically connected via through silicon vias (TSVs) or may be disconnected from each other.

In the present exemplary embodiment, notches may be provided on the side faces of the first sub-die 42 and the third sub-die 44, and the electrodes 6 may be formed in the notches. Each of the electrodes 6 may be electrically connected to at least one of the wiring layers. The electrode 6 disposed on the first sub-die 42 may electrically connect the wiring layer on the first die 41 and the wiring layer on the first sub-die 42. The electrode 6 disposed on the third sub-die 44 may electrically connect the wiring layer on the second sub-die 42 and the wiring layer on the third sub-die 44. The notch and the electrode 6 can be formed by removing a portion of the die. That is, a TSV may be formed at a position where the electrode 6 needs to be formed, and then a part of the die may be removed to expose the TSV to form the electrode 6. When the TSV penetrates through a layer of die, the length of the electrode 6 in the thickness direction of the die may be greater than or equal to the thickness of the die. When the TSV penetrates through two or more layers of dies, the length of the electrode 6 in the thickness direction of the die may be greater than the thickness of the die. Certainly, in other exemplary embodiments of the invention, the electrodes 6 may be disposed directly on the sides of the die without having to be disposed within the notches.

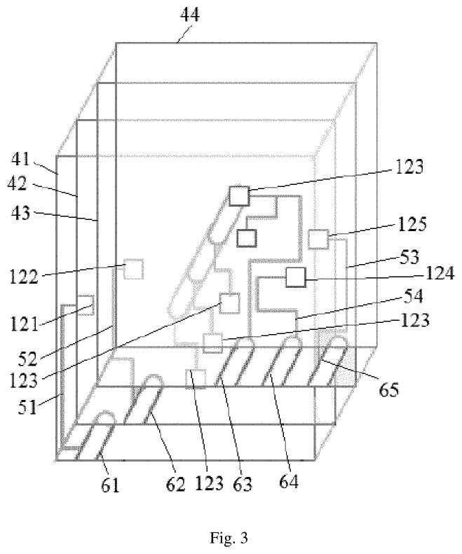

Referring to the schematic perspective view of the semiconductor device shown in FIG. 3, five electrodes 6 may be formed on the same side surface of the stacked structure. These electrodes 6 may be referred to as the first electrode 61, the second electrode 62, the third electrode 63, and the fourth electrode 64 and the fifth electrode 65, respectively.

The first electrode 61 may be electrically connected to the first signal terminal 121 through the first wiring layer 51. The second electrode 62 may be electrically connected to the second signal terminal 122 through the second wiring layer 52. The third signal terminal 123 of the first wiring layer 51, the third signal terminal 123 of the second wiring layer 52, the third signal terminal 123 of the third wiring layer 53, and the third signal terminal 123 of the fourth wiring layer 54 may be electrically connected to each other via the TSVs, which may then be connected to the third electrode 63. That is, the third electrode 63 may be electrically connected to the third signal terminals 123 through the first wiring layer 51, the second wiring layer 52, the third wiring layer 53 and the fourth wiring layer 54. The fourth electrode 64 may be electrically connected to the fourth signal terminal 124 through the fourth wiring layer 54. The fifth electrode 65 may be electrically connected to the fifth signal terminal 125 through the third wiring layer 53. In the semiconductor device described above, individual signals on individual dies can be individually controlled by electrodes, and multiple signals on multiple dies can be collectively controlled. Whether individual control or collective control is implemented may be determined according to the requirements of the signals. Certainly, the first electrode 61 may also electrically connect the first wiring layer 51 and the second wiring layer 52. The first wiring layer 51 and the second wiring layer 52 may be connected through TSVs and then electrically connected to the first electrode 61. The first wiring layer 51 and the second wiring layer 52 may also be provided with connecting wires and then be electrically connected directly through the first electrode 61.

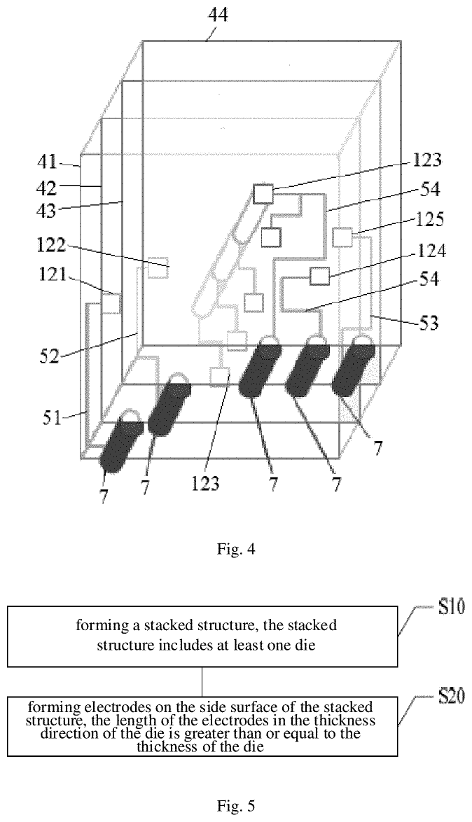

FIG. 4 is a schematic view of a semiconductor device in accordance with one embodiment of the present invention. Referring to FIG. 4, the semiconductor device may further include a bump 7 disposed on a side of the electrode 6 facing away from the die. The bump 7 may protrude from the notch. That is, the bump 7 may cover the position where the electrode 6 is disposed. The bump 7 may cover the electrode 6 and the junction of the electrode 6 and the wiring layer. That is, the length of the bump 7 may be greater than or equal to the length of the electrode 6, and the width of the bump 7 may be greater than or equal to the width of the electrode 6. The bump 7 may electrically connect one or more selected dies in the multiple dies.

The present invention may further provide a method for fabricating a semiconductor device. FIG. 5 is a flow chart illustrating a method of fabricating a semiconductor device in accordance with one embodiment of the present invention. Referring to FIG. 5, the method for fabricating may include the following steps.

In step S10, a stacked structure may be formed. The stacked structure may include at least one die 8.

In step S20, electrodes 6 may be formed on the side surface of the stacked structure, and the length of the electrodes 6 in the thickness direction of the die 8 may be greater than or equal to the thickness of the die 8.

The steps of the method for fabricating the semiconductor device will be described in detail below.

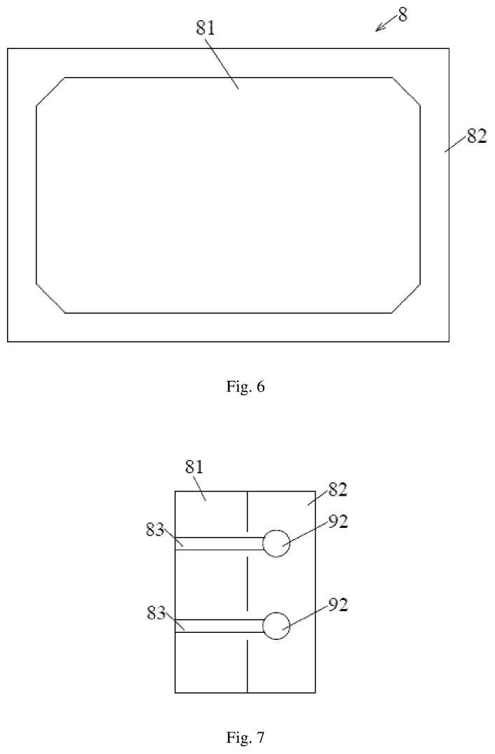

Before forming the stacked structure, a wiring layer may be formed on each of the dies 8. The method of fabricating the wiring layer may include, but not be limited to, a printing method or an evaporation method, which will not be described in detail herein. Referring to the structural diagram of the die shown in FIG. 6, the die 8 may include a circuit area 81 for accommodating a wiring layer and a sealing region 82 for encapsulating and sealing. On each of the dies 8, connecting wires 83 may be formed in the portion of the wiring layer for external connection, and the connecting wires 83 may be led out to the sealing region 82.

FIG. 7 is a schematic view showing the structure of forming a TSV in the sealing region of the die in accordance with one embodiment of the present invention. Referring to FIG. 7, while forming the first TSV 91, a second TSV 92 can be formed in the sealing region 82 of the die 8. The second TSV 92 may be connected to the above-described connecting wires 83 formed in the sealing region 82. The second TSV 92 may be formed simultaneously with the first TSV 91, thus reducing the complexity of the process.

In step S10, a stacked structure may be formed. The stacked structure may include at least one die.

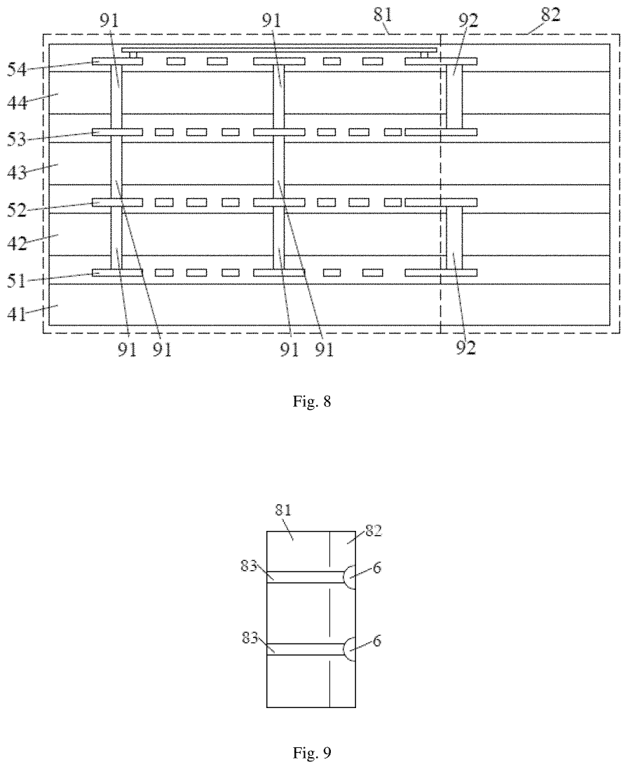

In the present exemplary embodiment, a four-layer die structure will be used as an example. FIG. 8 is a schematic view of a die after forming a stacked structure in accordance with one embodiment of the present invention. For the convenience of the following description, each die in the four-layer die structure may be referred to as the first die 41, the first sub-die 42, the second sub-die 43 and the third sub-die 44, respectively, from bottom to top.

The first TSV 91 may be formed in the first sub-die 42, the second sub-die 43 and the third sub-die 44. The first TSV 91 may be connected to the wiring layer on the first die 41, the wiring layer on the first sub-die 42, the wiring layer on the second sub-die 43 and the wiring layer on the third sub-die 44.

The first sub-die 42 may be formed on the first die 41, the second sub-die 43 may be formed on the first sub-die 42, and the third sub-die 44 may be formed on the second sub-die 43. Certainly, the number of dies can also be one, two, three, five or more. When the number of dies is one, since the die does not need to be connected to a die located underneath, the first TSV 91 may not be formed. The second TSV 92 may be directly formed in the sealing region 82 of the first die 41.

In step S20, an electrode 6 may be formed on the side surface of the stacked structure. The length of the electrode 6 in the thickness direction of the die may be greater than or equal to the thickness of the die.

FIG. 9 is a schematic view showing the structure after removing a part of the sealing region of the die in accordance with one embodiment of the present invention.

In the present exemplary embodiment, after the stacked structure is formed, a portion of the sealing region 82 and a portion of the second TSV 92 may be removed by grinding until reaching the diameter of the second TSV 92, so that the exposed second TSV 92 forms a rectangle connection plane, and the largest possible area of the connection plane may be achieved, facilitating subsequent formation and connection of bumps 7. The exposed second TSV 92 may form the electrode 6. Certainly, in some embodiments of the present invention, the electrode 6 may be formed by removing only a portion of the sealing region 82 without removing any portion of the second TSV 92 to expose the second TSV 92. Since the electrode 6 is formed based on the second TSV 92, the length of the electrode 6 in the thickness direction of the die may be larger than the thickness of the die. In the case where the second TSV 92 is formed at the same position of two dies, the length of the electrode 6 in the thickness direction of the die may be larger than the thickness of the die. The connection surface of the electrode 6 formed by the second TSV 92 may have a larger contact area with the wiring layer, thereby providing a reliable connection. The method to form the electrode 6 is not limited to the above description. For example, the electrode 6 may be formed by direct vapor deposition or printing on the side surface of the stacked structure.

The electrode 6 shown in FIG. 9 is formed on one side surface of the stacked structure. Certainly, the electrode 6 may be disposed on both side surfaces or a plurality of side surfaces of the stacked structure, all of which are within the scope of the present invention.

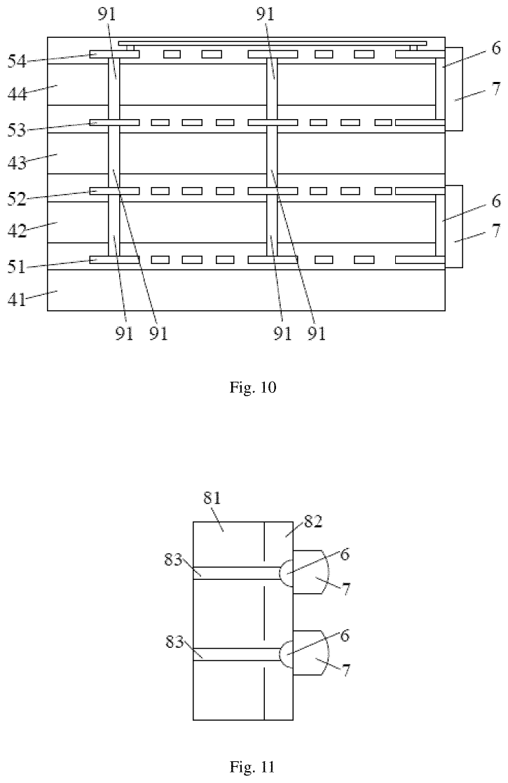

In the present exemplary embodiment, after the electrode 6 is formed, the fabrication method may further include: forming bumps 7 on the side of the electrode 6 facing away from the die. FIG. 10 is a schematic view of a stacked structure after forming a bump in accordance with one embodiment of the present invention. FIG. 11 is a partial top view of the structure of FIG. 10. Referring to FIGS. 10 and 11, the bumps 7 may be arranged in a strip shape, and the bumps 7 may be provided on the side of the electrode 6 facing away from the die 8. That is, the bumps 7 may cover the position where the electrodes 6 of the die 8 are disposed. The bumps 7 may cover the electrode 6 and the junction of the electrode 6 and the wiring layer. That is, the length of each bump 7 may be greater than or equal to the length of the electrode 6, and the width of each bump 7 may be greater than or equal to the width of the electrode 6.

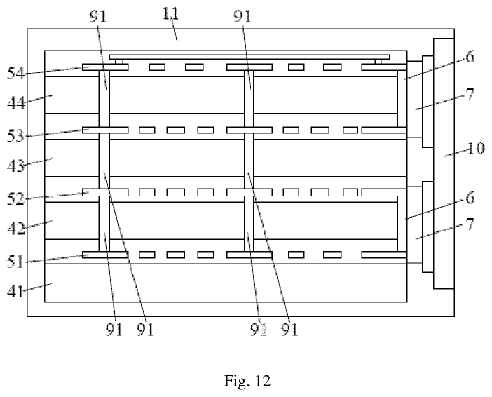

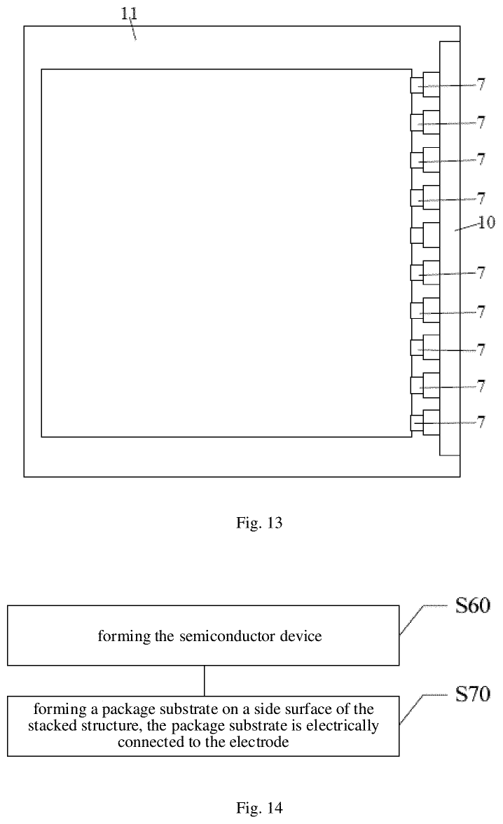

The present invention further provides a semiconductor package. FIG. 12 is a schematic view of a semiconductor package in accordance with one embodiment of the present invention. FIG. 13 is a top view of the structure of FIG. 12. Referring to FIGS. 12 and 13, the semiconductor package may include a semiconductor device, a package substrate 10 and a package film 11. The package substrate 10 may be disposed on a side surface of the stacked structure and may be electrically connected to the electrode 6. The package film 11 may be disposed on the surface of the stacked structure not disposed with the package substrate 10.

The semiconductor device may be the device in any of the aforementioned embodiments. The specific structure of the semiconductor device has been described in detail above, and therefore will not be described herein.

In the present exemplary embodiment, one package substrate 10 may be provided and may be disposed on the side of the stacked structure on which the electrodes 6 are disposed. Certainly, in the case where the plurality of side surfaces of the stacked structure is disposed with the electrodes 6, a plurality of the package substrate 10 may be provided, all of which may be disposed on the side surfaces of the stacked structure. The encapsulating film 11 may be disposed on the upper and lower surfaces of the stacked structure, thereby increasing the heat dissipation area of the semiconductor package.

The upper and lower surfaces of the stacked structure can be used as a heat dissipating surface to increase the effective heat dissipating area, accommodating for memories of higher capacity. Moreover, the package substrate 10 may be disposed on the side surface of the stacked structure, thereby facilitating the miniaturization of the device.

The present invention further provides a method for fabricating a semiconductor package. FIG. 14 is a flow chart illustrating a method of fabricating a semiconductor package in accordance with one embodiment of the present invention. Referring to FIG. 14, the method may include the following steps.

In step S60, a semiconductor device may be formed. The semiconductor device may be the device in one of the aforementioned embodiments.

In step S70, a package substrate 10 may be formed on a side surface of the stacked structure. The package substrate may be electrically connected to the electrode 6.

In the present exemplary embodiment, the package film 11 may be formed on the surface of the stacked structure no disposed with the package substrate 10.

The features, structures or characteristics described above may be combined in any suitable manner in one or more embodiments, and the features discussed in the various embodiments are interchangeable, if possible. In the above description, numerous specific details are provided to give a thorough understanding of the embodiments of the present invention. However, one skilled in the art will appreciate that the technical solution of the present invention may be practiced without one or more of the specific details, or other methods, components, materials, and the like may be employed.

In other instances, well-known structures, materials or operations are not shown or described in detail to avoid obscuring aspects of the invention.

Although the relative terms such as “upper” and “lower” are used in the specification to describe the relative relationship of one component of the icon to another component, these terms are used in this specification for convenience only, for example, according to the accompanying drawings. The direction of the example described. It will be understood that if the device of the icon is flipped upside down, the component “upper” will become the component “lower”. Other relative terms such as “high”, “low”, “top” and “bottom” also have similar meanings. When a structure is “on” another structure, it may mean that a structure is integrally formed on another structure, or that a structure is “directly” disposed on another structure, or that a structure is “indirectly” disposed through another structure.

In the present specification, the terms “a”, “an”, “the”, “the said”, “at least one” are used to mean the meaning of the open type and means that there may be additional elements/components/etc. in addition to the listed elements/components/etc. The terms “first”, “second”, and “third”, etc. are used only as markers, not the number of objects.

It should be understood that the present invention does not limit its application to the detailed structure and arrangement of the components presented in the specification. The present invention is capable of other embodiments and of various embodiments. The foregoing variations and modifications are intended to fall within the scope of the present invention. It is to be understood that the present invention disclosed and claimed herein extends to all alternative combinations of two or more individual features that are mentioned or apparent in the drawings. All of these different combinations constitute a number of alternative aspects of the present invention. The embodiments described in the specification are illustrative of the best mode of the present invention and will enable those skilled in the art to utilize this present invention.

1. A semiconductor device, comprising:
a stacked structure comprising a plurality of dies;
an electrode formed on a side surface of the stacked structure, the electrode having a length greater than or equal to a thickness of the die in a thickness direction of the stacked structure; and
a bump covering the electrode and disposed on a side of the electrode facing away from the plurality of dies, the bump electrically connecting one or more selected dies in the plurality of dies.

2. The semiconductor device of claim 1, further comprising:
a wiring layer formed on each of the plurality of dies; and
a plurality of signal terminal disposed in each of the wiring layers and electrically connected to the electrode via the wiring layers.

3. The semiconductor device of claim 1, wherein the bump covers junctions of the electrode and the wiring layers.

4. The semiconductor device of claim 1, wherein the length of the bump is greater than or equal to the length of the electrode, and the width of the bump is greater than or equal to the width of the electrode.

5. A semiconductor package, comprising:
the semiconductor device of claim 1; and
a package substrate disposed on a side surface of the stacked structure and electrically connected to the electrode.

6. The package of claim 5, further comprising:
a package film disposed on a surface of the stacked structure not disposed with the package substrate.

7. A semiconductor device, comprising:
a stacked structure comprising at least one die; and
an electrode formed on a side surface of the stacked structure, the electrode having a length greater than or equal to a thickness of the die in a thickness direction of the die.

8. The semiconductor device of claim 7, further comprising:
a wiring layer formed on the die; and
a plurality of signal terminals disposed in the wiring layer and electrically connected to the electrode via the wiring layer.

9. The semiconductor device of claim 7, wherein the stacked structure comprises:
a first die; and
a second die formed on the first die.

10. The semiconductor device of claim 9, further comprising:
a first wiring layer disposed on the first die; and
a second wiring layer disposed on the second die, wherein the first wiring layer is electrically connected to the second wiring layer through a Through Silicon Via (TSV).

11. The semiconductor device of claim 10, wherein the electrode is electrically connected to at least one of the first wiring layer and the second wiring layer.

12. The semiconductor device of claim 8, wherein the die has a notch and the electrode is disposed in the notch.

13. The semiconductor device of claim 12, further comprising:
a bump disposed on a side of the electrode facing away from the die, the bump protruding from the notch.

14. The semiconductor device of claim 13, wherein the bump covers the electrode and a junction of the electrode and the wiring layer.

15. A method of fabricating a semiconductor device, comprising:
forming a stacked structure, the stacked structure comprising at least one die; and
forming an electrode on a side surface of the stacked structure, the electrode having a length greater than or equal to a thickness of the die in a thickness direction of the die.

16. The method of claim 15, further comprising: before forming a stacked structure, forming a wiring layer on the die, wherein the electrode is electrically connected to the wiring layer.

17. The method of claim 15, wherein forming a stacked structure comprises:
forming a first die; and
forming a second die on the first die.

18. The method of claim 17, further comprising:
forming a first wiring layer on the first die;
forming a second wiring layer on the second die; and
forming a first TSV on the first die, the first TSV electrically connecting the first wiring layer and the second wiring layer.

19. The method of claim 18, further comprising:
forming a second TSV in a sealing region of the second die while forming the first TSV.

20. The method of claim 19, wherein forming an electrode on a side surface of the stacked structure comprises:
removing at least a portion of the sealing region to expose the second TSV to form the electrode, the electrode arranged on the side surface of the stacked structure.
